(19) United States
(12) Patent Application Publication
(10) Pub. No.: US 2024/0304607 A1
(43) Pub. Date: Sep. 12, 2024

(54) SEMICONDUCTOR DEVICE, AND MANUFACTURING METHOD THEREOF

(71) Applicant: Kioxia Corporation, Tokyo (JP)

(72) Inventor: Kazuma HASEGAWA, Fujisawa Kanagawa (JP)

(21) Appl. No.: 18/596,528

(22) Filed: Mar. 5, 2024

(30) Foreign Application Priority Data
Mar. 7, 2023 (JP) 2023-034805

(51) Int. Cl. H01L 25/10; H01L 23/00; H01L 23/31; H10B 80/00

(52) U.S. Cl. CPC H01L 25/105; H01L 23/3128; H01L 24/48; H01L 24/85; H01L 24/96; H10B 80/00; H01L 2224/48145; H01L 2224/48225; H01L 2224/85801; H01L 2224/96; H01L 2225/1052; H01L 2924/1438

(57) ABSTRACT

A semiconductor device includes a substrate that includes a first surface, a first semiconductor chip that includes a second surface facing the first surface of the substrate and a third surface opposite to the second surface, each of the second and third surfaces having a rectangular shape that includes a plurality of sides and has surface areas that are different, and a second semiconductor chip disposed on the first surface of the substrate on one side of the first semiconductor chip. When viewed in a first direction substantially perpendicular to the substrate, one of the sides of the third surface that is closest to the second semiconductor chip overlaps an interior portion of the second semiconductor chip.

### CROSS-REFERENCE TO RELATED APPLICATION(S)

This application is based upon and claims the benefit of priority from Japanese Patent Application No. 2023-034805, filed Mar. 7, 2023, the entire contents of which are incorporated herein by reference.

### FIELD

Embodiments described herein relate generally to a semiconductor device, and to a manufacturing method thereof.

### BACKGROUND

In some semiconductor device packages, a spacer chip is provided on a substrate, and a stacked body for memory chips is provided on the spacer chip. In such a case, a controller chip is disposed on the substrate so that the package size can be reduced. However, because of the use of the spacer chip, both the assembly cost and the number of processes increase.

### BRIEF DESCRIPTION OF THE DRAWINGS

FIG. 1 is a sectional view showing a configuration of a semiconductor

device according to a first embodiment.

FIG. 2 is a plan view showing a configuration of the semiconductor device according to the first embodiment.

FIG. 3 is a sectional view showing a configuration of the semiconductor device according to the first embodiment.

FIG. 4A is a drawing showing a method of manufacturing the semiconductor device according to the first embodiment.

FIG. 4B is a drawing showing the manufacturing method, continuing from FIG. 4A.

FIG. 4C is a drawing showing the manufacturing method, continuing from FIG. 4B.

FIG. 4D is a drawing showing the manufacturing method, continuing from FIG. 4C.

FIG. 4E is a drawing showing the manufacturing method, continuing from FIG. 4D.

FIG. 4F is a drawing showing the manufacturing method, continuing from FIG. 4E.

FIG. 4G is a drawing showing the manufacturing method, continuing from FIG. 4F.

FIG. 5 is a drawing showing a method of manufacturing the semiconductor device according to the first embodiment.

FIG. 6 is a drawing showing a method of manufacturing the semiconductor device according to the first embodiment.

FIG. 7 is a drawing showing a method of manufacturing the semiconductor device according to the first embodiment.

FIG. 8 is a sectional view showing a configuration of a semiconductor

device according to a comparative example.

FIG. 9 is a sectional view showing a configuration of a semiconductor device according to a second embodiment.

FIG. 10 is a sectional view showing a configuration of a semiconductor device according to a third embodiment.

FIG. 11A is a sectional view showing a method of manufacturing the semiconductor device according to the third embodiment.

FIG. 11B is a drawing showing the manufacturing method, continuing

from FIG. 11A.

FIG. 11C is a drawing showing the manufacturing method, continuing from FIG. 11B.

FIG. 11D is a drawing showing the manufacturing method, continuing from FIG. 11C.

FIG. 11E is a drawing showing the manufacturing method, continuing from FIG. 11D.

FIG. 12A is a sectional view showing a method of manufacturing a semiconductor device according to a modification of the third embodiment.

FIG. 12B is a drawing showing the manufacturing method, continuing from FIG. 12A.

FIG. 12C is a drawing showing the manufacturing method, continuing from FIG. 12B.

FIG. 13 is a sectional view showing a configuration of a semiconductor device according to a fourth embodiment.

FIG. 14 is a sectional view showing a configuration of a semiconductor device according to a fifth embodiment.

FIG. 15 is a sectional view showing a configuration of a semiconductor device according to a sixth embodiment.

FIG. 16 is a sectional view showing a configuration of a semiconductor device according to a seventh embodiment.

FIG. 17 is a sectional view showing a configuration of a semiconductor device according to an eighth embodiment.

FIG. 18 is a sectional view showing a configuration of a semiconductor device according to a ninth embodiment.

FIG. 19 is a sectional view showing a configuration of a semiconductor device according to a tenth embodiment.

FIG. 20 is a sectional view showing a configuration of a semiconductor device according to an eleventh embodiment.

FIG. 21 is a sectional view showing of a configuration of a semiconductor device according to a twelfth embodiment.

FIG. 22 is a sectional view showing of a configuration of a semiconductor device according to a thirteenth embodiment.

### DETAILED DESCRIPTION

Embodiments provide a semiconductor device, and a manufacturing method thereof, such that a semiconductor chip can be more appropriately disposed, without using a spacer.

In general, according to one embodiment, a semiconductor device comprises a substrate that includes a first surface; a first semiconductor chip that includes a second surface facing the first surface of the substrate and a third surface opposite to the second surface, each of the second and third surfaces having a rectangular shape that includes a plurality of sides and has surface areas that are different; and a second semiconductor chip disposed on the first surface of the substrate on one side of the first semiconductor chip. When viewed in a first direction substantially perpendicular to the substrate, one of the sides of the third surface that is closest to the second semiconductor chip overlaps an interior portion of the second semiconductor chip.

Hereafter, embodiments according to the present disclosure will be described, with reference to the drawings. The embodiments do not limit the disclosure. The drawings are schematic or conceptual, and ratios and the like of the portions are not necessarily the same as actual ratios. In the specification and the drawings, the same reference signs are allotted to elements the same as elements already mentioned in relation to a previous drawing, and a detailed description is omitted as appropriate.

### First Embodiment

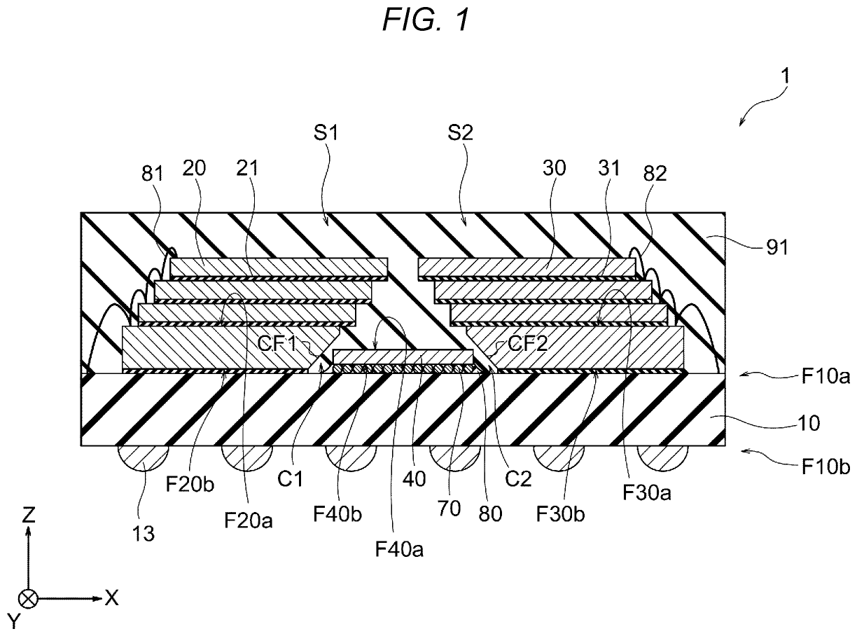

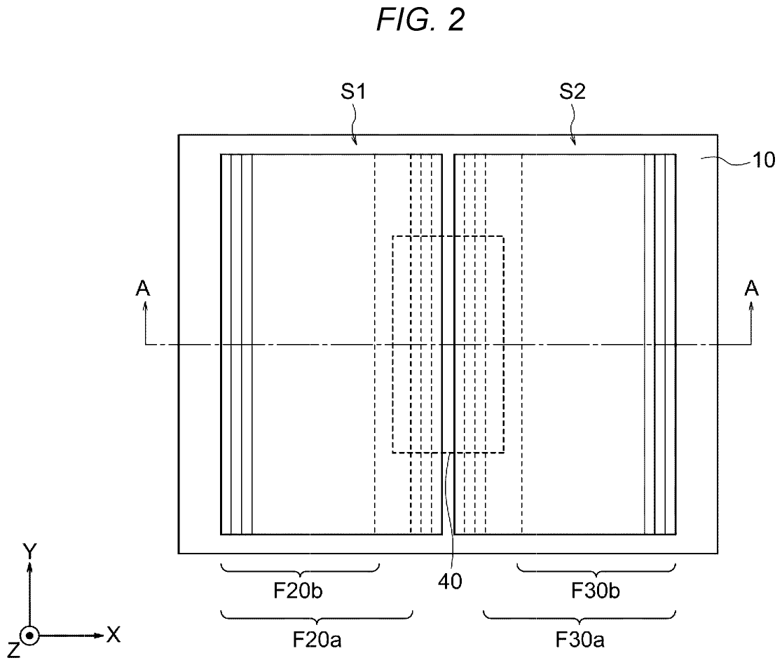

FIG. 1 is a sectional view showing a configuration of a semiconductor device 1 according to a first embodiment. FIG. 2 is a plan view showing a configuration of the semiconductor device 1 according to the first embodiment. The A-A line of FIG. 2 indicates a cross-section corresponding to FIG. 1.

The semiconductor device 1 includes a wiring substrate 10, stacked bodies S1 and S2, a semiconductor chip 40, bonding wires 81 and 82, and a sealing resin 91. The semiconductor device 1 is, for example, a package of a NAND flash memory.

FIG. 1 shows an X direction and a Y direction, which are parallel to a surface of the wiring substrate 10 and perpendicular to each other, and a Z direction, which is perpendicular to the surface of the wiring substrate 10. In the specification, a +Z direction is referred to as an upward direction and a −Z direction is referred to as a downward direction. The −Z direction may or may not correspond to a direction of gravitational force.

The wiring substrate 10 is a printed substrate or interposer including a wiring layer (not shown) and an insulating layer (not shown). A low-resistance metal such as copper (Cu), nickel (Ni), or an alloy thereof is used for the wiring layer. An insulating material such as a glass epoxy resin is used for the insulating layer. The wiring substrate 10 may have a multilayer wiring structure including a multiple of wiring layers and a multiple of insulating layers being stacked. The wiring substrate 10 may have a through via that penetrates a front surface and a back surface thereof, as is the case with, for example, an interposer.

A solder resist layer provided on the wiring layer is provided on a front surface F10a of the wiring substrate 10. The solder resist layer protects the wiring layer, and is also used in the insulating layer, which restricts short-circuiting problems. A pad (not shown) is provided on the front surface of the wiring substrate 10. The pad is a wiring layer that is exposed in the solder resist layer. The pad is connected to the bonding wires 81 and 82, a metal material 70, and the like. The pad is, for example, a gold (Au) plated electrode.

A solder resist layer provided on the wiring layer is provided on a back surface F10b of the wiring substrate 10. A metal bump 13 is provided on the wiring layer exposed in the solder resist layer. The metal bump 13 is provided in order to electrically connect another, unshown part and the wiring substrate 10.

The stacked body S1 has a semiconductor chip 20 and an adhesive layer 21. The adhesive layer 21 is, for example, a die attachment film (DAF) or a non-conductive paste (NCP). In the stacked body S1, a multiple of semiconductor chips 20 are stacked deviating in a direction (for example, a +X direction) perpendicular to a stacking direction (for example, the Z direction). Also, the stacked body S1 is provided on the surface F10a.

The semiconductor chip 20 is, for example, a memory chip including a NAND flash memory. The semiconductor chip 20 has a semiconductor element (not shown) on a front or upper surface F20a thereof. It is sufficient that the semiconductor element is, for example, a memory cell array and a peripheral circuit (e.g., a complementary metal-oxide-semiconductor (CMOS) circuit) thereof. The memory cell array may be a three-dimensional memory cell array such that a multiple of memory cells are disposed three-dimensionally. In the drawing, the semiconductor chips 20 are stacked as four memory chips. However, the number of semiconductor chips stacked may be three or less, or may be five or more.

Also, the semiconductor chip 20 has surfaces F20a and F20b. The surface F20b is a surface opposing the wiring substrate 10. The surface F20a is a surface on a side opposite to that of the surface F20b.

Also, the lowermost semiconductor chip 20 is thicker than the semiconductor chips 20 on a second level to a fourth level. The thickness of the semiconductor chip 20 is a thickness in the Z direction. Details of the lowermost semiconductor chip 20 will be described hereafter.

The stacked body S2 has a semiconductor chip 30 and an adhesive layer 31. The adhesive layer 31 is, for example, a die attachment film (DAF) or a non-conductive paste (NCP). In the stacked body S2, a multiple of semiconductor chips 20 are stacked deviating in a direction (for example, a −X direction) perpendicular to a stacking direction (for example, the Z direction). Also, the stacked body S2 is provided in a position on the surface F10a approximately parallel in the X direction to the surface F10a from the position of the stacked body S1.

The semiconductor chip 30 is, for example, a memory chip including a NAND flash memory. The semiconductor chip 30 has a semiconductor element (not shown) on a front or upper surface F30a thereof. The semiconductor element is, for example, a memory cell array and a peripheral circuit (e.g., a CMOS circuit) thereof. The memory cell array may be a three-dimensional memory cell array such that a multiple of memory cells are disposed three-dimensionally. In the drawing, the semiconductor chips 30 are stacked as four memory chips. However, the number of semiconductor chips stacked may be three or less, or may be five or more.

Also, the semiconductor chip 20 has the surfaces F20a and F20b. The surface F20b is a surface opposing the wiring substrate 10. The surface F20a is a surface on a side opposite to that of the surface F20b.

Also, the lowermost semiconductor chip 30 is thicker than the semiconductor chips 30 on a second level to a fourth level. The thickness of the semiconductor chip 30 is a thickness in the Z direction. Details of the lowermost semiconductor chip 30 will be described hereafter.

The semiconductor chip 40 is, for example, a controller chip that controls a memory chip. A semiconductor element (not shown) is provided on a surface, which opposes the wiring substrate 10, of the semiconductor chip 40. The semiconductor element is, for example, a complementary metal-oxide-semiconductor (CMOS) circuit that functions as a controller. An electrode pillar (not shown) electrically connected to the semiconductor element is provided on a surface F40b, which is a back or lower surface of the semiconductor chip 40. A low resistance metal material such as copper, nickel, or an alloy thereof is used for the electrode pillar.

Also, the semiconductor chip 40 is provided on the surface F10a. The semiconductor chip 40 is provided, for example, between the stacked bodies S1 and S2.

Also, the semiconductor chip 40 has surfaces F40a and F40b. The surface F40b is a surface that opposes the wiring substrate 10. The surface F40a is a surface on a side opposite to that of the surface F40b.

The metal material 70 is provided in a periphery of the electrode pillar, which acts as a connection bump. The electrode pillar is electrically connected via the metal material 70 to the wiring layer exposed in an aperture portion of the solder resist layer. A low resistance metal material such as a solder, silver, or copper is used for the metal material 70. The metal material 70 electrically connects the electrode pillar of the semiconductor chip 40 and the wiring layer of the wiring substrate 10.

A resin layer 80 is provided in a region in a periphery of the metal material 70, and in a region between the semiconductor chip 40 and the wiring substrate 10. The resin layer 80 is, for example, formed by curing an underfill resin, and covers, thereby protecting, a periphery of the semiconductor chip 20.

The bonding wire 81 is connected to any pad of the wiring substrate 10 and the semiconductor chip 20. The bonding wire 82 is connected to any pad of the wiring substrate 10 and the semiconductor chip 30. The bonding wires 81 and 82 are, for example, gold (Au) wires. In order to connect using the bonding wires 81 and 82, the semiconductor chips 20 and 30 are stacked deviating by an amount equivalent to a pad (not shown).

In the example shown in FIG. 1, a direction in which the stacked body S1 deviates (i.e., an offset direction of the semiconductor chip 20) is the +X direction. A direction in which the stacked body S2 deviates (i.e., an offset direction of the semiconductor chip 30) is the −X direction. The bonding wire 81 to be connected to the semiconductor chip 20 of the stacked body S1 is provided on a side opposite to that of the stacked body S2. The bonding wire 82 to be connected to the semiconductor chip 30 of the stacked body S2 is provided on a side opposite to that of the stacked body S1.

Furthermore, the sealing resin 91 seals the stacked bodies S1 and S2, the semiconductor chip 40, the bonding wires 81 and 82, and the like. Because of this, the stacked bodies S1 and S2 and the semiconductor chip 40 form one semiconductor package on the wiring substrate 10.

Next, details of the lowermost semiconductor chip 20 will be described.

An area of the surface F20b is smaller than an area of the surface F20a. Also, an outer edge of the surface F20b on the semiconductor chip 40 side is farther to an inner side than an outer edge of the surface F20a when seen from the Z direction.

Also, at least one portion of the semiconductor chip 40 (i.e., the surface F40b) on the semiconductor chip 20 side coincides with the surface F20a when seen from the Z direction.

As shown in FIG. 1, the lowermost semiconductor chip 20 further has a cutout portion C1. The cutout portion C1 is provided in a corner portion in which a side surface between the surface F20b and the surface F20a and the surface F20b intersect. The cutout portion C1 is provided on the semiconductor chip 40 side.

When seen from the Z direction, at least one portion of the semiconductor chip 40 (i.e., the surface F40b) on the semiconductor chip 20 side coincides with a cutout surface CF1 of the cutout portion C1. In the example shown in FIG. 1, the cutout surface CF1 of the cutout portion C1 is provided inclined with respect to a Z axis and an X axis. That is, the cutout surface CF1 is an inclined surface.

Next, details of the lowermost semiconductor chip 30 will be described.

An area of the surface F30b is smaller than an area of the surface F30a. Also, an outer edge of the surface F30b on the semiconductor chip 40 side is farther to an inner side than an outer edge of the surface F30a when seen from the Z direction.

Also, at least one portion of the semiconductor chip 40 (i.e., the surface F40b) on the semiconductor chip 30 side coincides with the surface F30a when seen from the Z direction.

As shown in FIG. 1, the lowermost semiconductor chip 30 further has a cutout portion C2. The cutout portion C2 is provided in a corner portion in which a side surface between the surface F30b and the surface F30a and the surface F30b intersect. The cutout portion C2 is provided on the semiconductor chip 40 side.

When seen from the Z direction, at least one portion of the semiconductor chip 40 (i.e., the surface F40b) on the semiconductor chip 30 side coincides with a cutout surface CF2 of the cutout portion C2. In the example shown in FIG. 1, the cutout surface CF2 of the cutout portion C2 is provided inclined with respect to a Z axis and an X axis. That is, the cutout surface CF2 is an inclined surface.

As shown in FIG. 1, the lowermost semiconductor chips 20 and 30 are thicker than the semiconductor chips 20 and 30 on the second level to the fourth level. Also, as shown in FIGS. 1 and 2, the cutout portions C1 and C2 are provided, and the lowermost semiconductor chips 20 and 30 are disposed in such a way as to be in proximity to the semiconductor chip 40. Because of this, the semiconductor chips 20 and 30 can be provided above the semiconductor chip 40. As a result of this, a necessary area of the package can be reduced.

The surfaces F20a and F30a are surfaces on which a semiconductor element is provided. Thicknesses of the semiconductor chips 20 and 30 from the surfaces F20a and F30a on the semiconductor chip 40 side are preferably a predetermined thickness or greater. The predetermined thickness is determined depending on the region of the semiconductor element. Because of this, an effect on an operation of the semiconductor element can be restricted. The predetermined thickness is, for example, 30 μm.

Next, the adhesive layers 21 and 31 will be described.

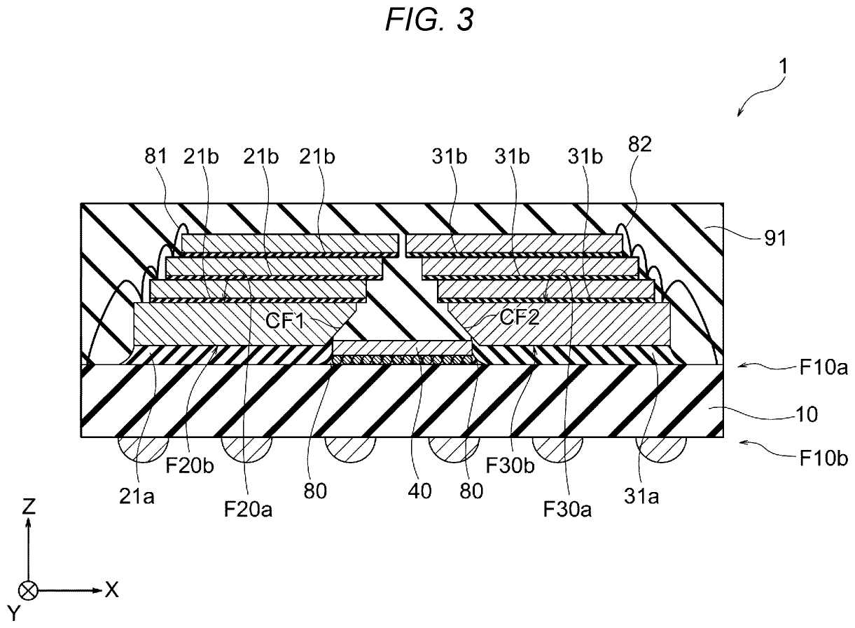

FIG. 3 is a sectional view showing a configuration of the semiconductor device 1 according to the first embodiment. FIG. 3 is a drawing illustrating details of the adhesive layers 21 and 31.

The adhesive layer 21 has adhesive layers 21a and 21b.

The adhesive layer 21a is provided below the lowermost semiconductor chip 20. The adhesive layer 21a is an NCP.

A viscosity of an NCP is lower than a viscosity of a DAF. A form of the adhesive layer 21a protruding from the lowermost semiconductor chip 20 is determined in accordance with the viscosity of the adhesive layer 21a. An end surface of the adhesive layer 21a on a side opposite to that of the semiconductor chip 40 has a form such that a hem is spread out in a raised form. An end surface of the adhesive layer 21a on the semiconductor chip 40 side has a form that crawls upward along an end surface of the resin layer 80 and a side surface of the semiconductor chip 40.

The adhesive layer 21b is provided below the semiconductor chips 20 on the second level to the fourth level. The adhesive layer 21b is a DAF.

The adhesive layer 31 has adhesive layers 31a and 31b.

The adhesive layer 31a is provided below the lowermost semiconductor chip 30. The adhesive layer 31a is an NCP.

A form of the adhesive layer 31a is approximately the same as the form of the adhesive layer 21a.

The adhesive layer 31b is provided below the semiconductor chips 30 on the second level to the fourth level. The adhesive layer 31b is a DAF.

In the example shown in FIG. 3, the adhesive layers 21a and 31a are not provided above the semiconductor chip 40. That is, the adhesive layers 21a and 31a positioned higher than the position of the semiconductor chip 40 are farther to an outer side than the semiconductor chip 40 when seen from the Z direction. The adhesive layers 21a and 31a may also be above the semiconductor chip 40.

Also, the adhesive layers 21a and 31a are hardly provided at all on the cutout surfaces CF1 and CF2. Consequently, the cutout surfaces CF1 and CF2 are in contact with the sealing resin 91, which covers the semiconductor chips 30 and 40.

Next, a method of manufacturing the semiconductor device 1 will be described.

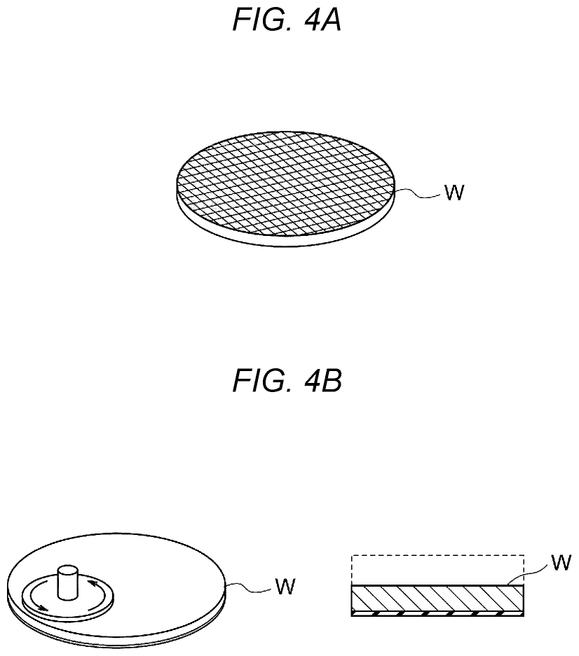

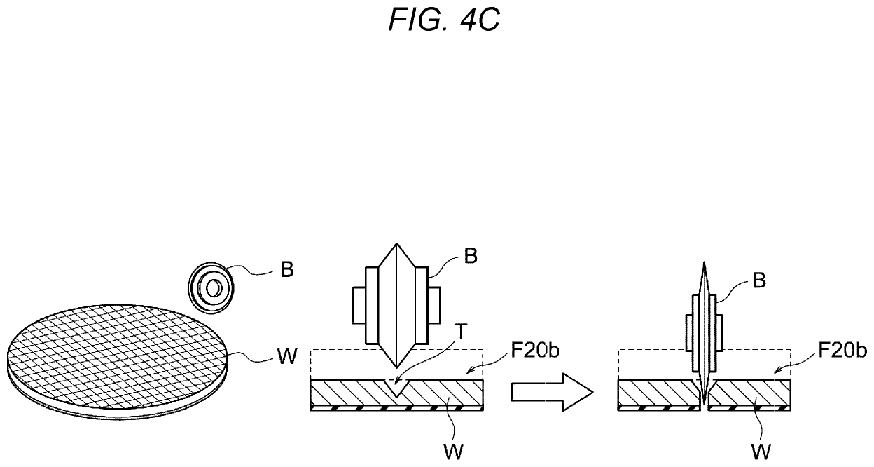

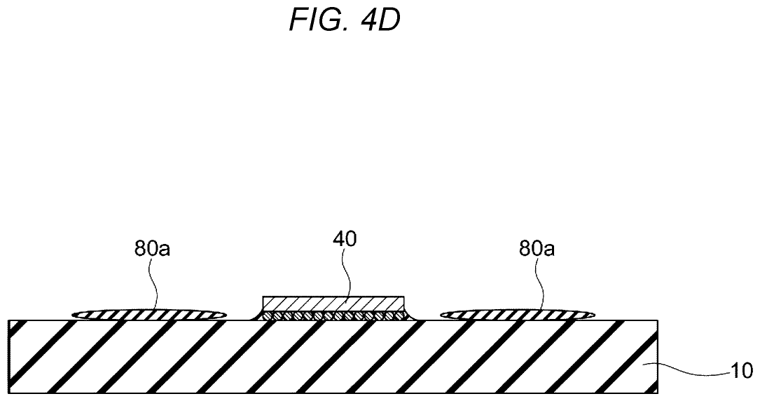

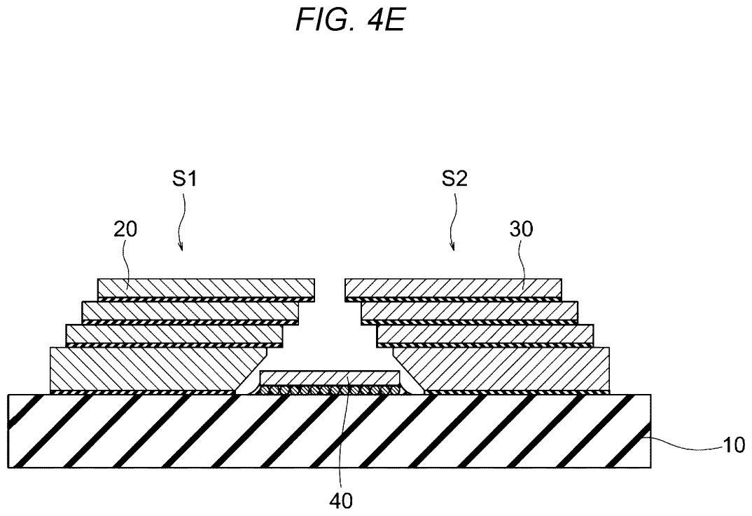

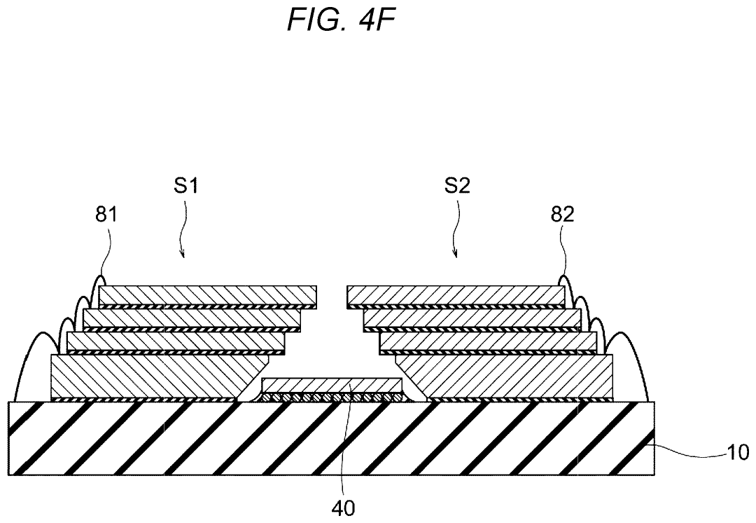

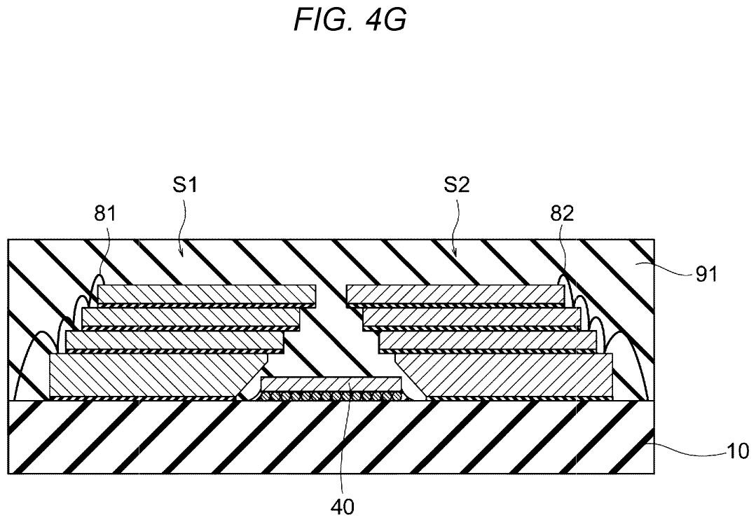

FIGS. 4A to 4G are drawings showing a method of manufacturing the semiconductor device 1 according to the first embodiment.

Firstly, as shown in FIG. 4A, a wafer W on which semiconductor elements of the semiconductor chips 20 and 30 are formed is prepared.

Next, as shown in FIG. 4B, grinding of a back surface of the wafer W is carried out. A left side of FIG. 4B is a perspective view. A right side of FIG. 4B is a sectional view of the wafer W. In the example shown in FIG. 4B, a surface of the wafer W on which a semiconductor element is formed is oriented downward.

Next, as shown in FIG. 4C, dicing is carried out, thereby singulating the wafer W. In the example shown in FIG. 4C, blade dicing is carried out. A left side of FIG. 4C is a perspective view. A right side of FIG. 4C is a sectional view of the wafer W at two steps of dicing. In a first step of dicing, dicing is carried out using a comparatively thick blade B, whereby a recessed portion T corresponding to the cutout portions C1 and C2 (i.e., the cutout surfaces CF1 and CF2) is formed. The recessed portion T is formed in one portion of the wafer W along a dicing line. In a second step of dicing, dicing is carried out using a comparatively thin blade B, whereby the wafer B is cut through.

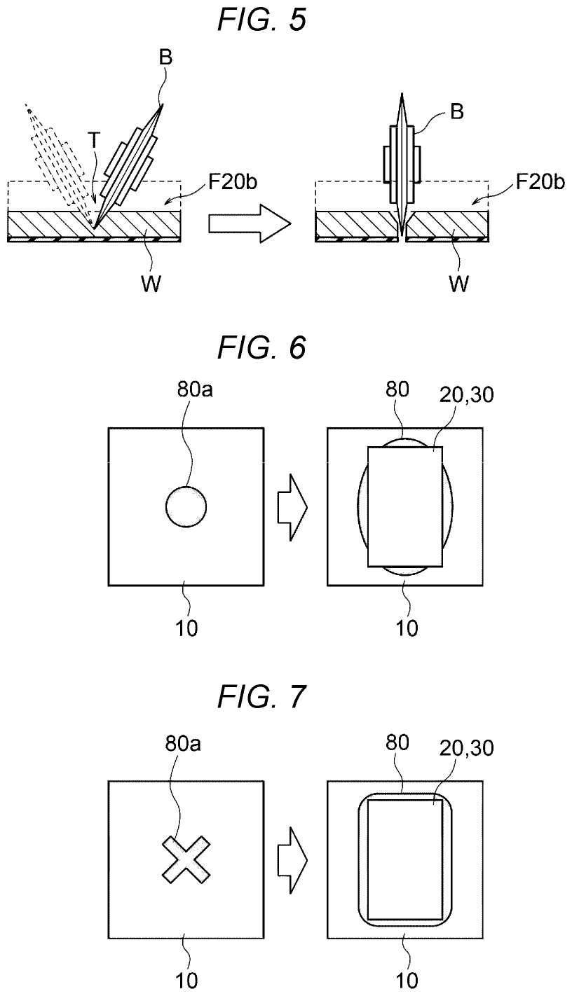

FIG. 5 is a drawing showing a method of manufacturing the semiconductor device 1 according to the first embodiment. FIG. 5 is a modification corresponding to the process shown in FIG. 4C. In the example shown in FIG. 5, the comparatively thick blade B is not used.

In the dicing in the first step, dicing is carried out twice using the blade B disposed in such a way as to be at an angle with respect to a normal direction of the plane of the wafer W, whereby the cutout portions C1 and C2 (i.e., the cutout surfaces CF1 and CF2) are formed. In the dicing in the second step, the wafer W is cut through in the same way as in the process shown in FIG. 4C.

Next, as shown in FIG. 4D, the semiconductor chip 40 is mounted on the wiring substrate 10, and a material 80a of the resin layer 80 (an NCP, for example) is applied onto the wiring substrate 10. A form of the resin layer 80 after a curing process changes in accordance with a form of the applied material 80a.

Each of FIGS. 6 and 7 shows a method of manufacturing the semiconductor device 1 according to the first embodiment. FIGS. 6 and 7 show a relationship between a form of the applied material 80a and a form of the protruding resin layer 80.

In the example shown in FIG. 6, the material 80a is applied in a circular form. In this case, protrusion of the resin layer 80 is large in portions on sides of the semiconductor chips 20 and 30, and becomes smaller in corner portions of the semiconductor chips 20 and 30.

In the example shown in FIG. 7, the material 80a is applied in an X form. In this case, protrusion of the resin layer 80 is comparatively uniform along an outer peripheral form of the semiconductor chips 20 and 30.

Next, as shown in FIG. 4E, the semiconductor chips 20 and 30 are mounted on the wiring substrate 10. By so doing, the stacked bodies S1 and S2 are formed.

Next, as shown in FIG. 4F, the bonding wires 81 and 82 are formed using wire bonding.

Next, as shown in FIG. 4G, the sealing resin 91 is formed.

Subsequently, the semiconductor device 1 shown in FIGS. 1 and 2 is completed by forming the metal bump 13.

According to the first embodiment, as heretofore described, the outer edges of the surfaces F20b and F30b on the semiconductor chip 40 side are farther to the inner side than the outer edges of the surfaces F20a and F30a on the semiconductor chip 40 side when seen from the Z direction. Also, at least one portion of the semiconductor chip 40 on the semiconductor chip 20 and 30 sides coincides with the surfaces F20a and F30a. Because of this, the semiconductor chips 20 and 30 and the semiconductor chip 40 can be disposed in proximity to each other. As a result of this, a necessary area of the package can be further reduced.

With regard to the semiconductor chips 20 on the second level to the fourth level, the area of the surface F20b is the same as the area of the surface F20a. With regard to the semiconductor chips 20 on the second level to the fourth level, the outer edge of the surface F20b approximately coincides with the outer edge of the surface F20a when seen from the Z direction.

Also, with regard to the semiconductor chips 30 on the second level to the fourth level, the area of the surface F30b is the same as the area of the surface F30a. With regard to the semiconductor chips 30 on the second level to the fourth level, the outer edge of the surface F30b approximately coincides with the outer edge of the surface F30a when seen from the Z direction.

### Comparative Example

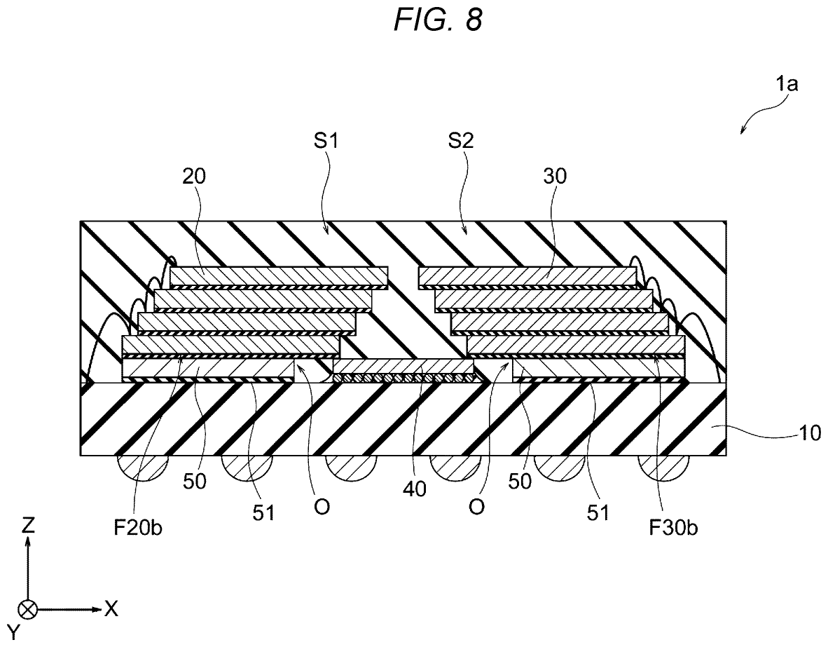

FIG. 8 is a sectional view showing a configuration of a semiconductor device la according to a comparative example.

In the comparative example, the semiconductor chips 20 and 30 are provided above the semiconductor chip 40 by the positions of the stacked bodies S1 and S2 being raised using a spacer 50. The spacer 50 is affixed to the wiring substrate 10 using an adhesive layer 51. In this case, however, a cost and the number of processes due to the spacer 50 increase. Also, stress concentrates on an overhanging portion O of the lowermost semiconductor chips 20 and 30. The overhanging portion O is a portion of the surfaces F20b and F30b of the lowermost semiconductor chips 20 and 30 that is in contact with an end portion of the spacer 50.

On the other hand, the lowermost semiconductor chips 20 and 30 are comparatively thick in the first embodiment. Because of this, there is no need to provide a spacer. As a result of this, cost is restricted, and the number of processes can be reduced. Also, in the first embodiment, the cutout portions C1 and C2 are provided. As the cutout surfaces CF1 and CF2 are inclined surfaces, stress can be distributed. As a result of this, reliability can be increased.

### Second Embodiment

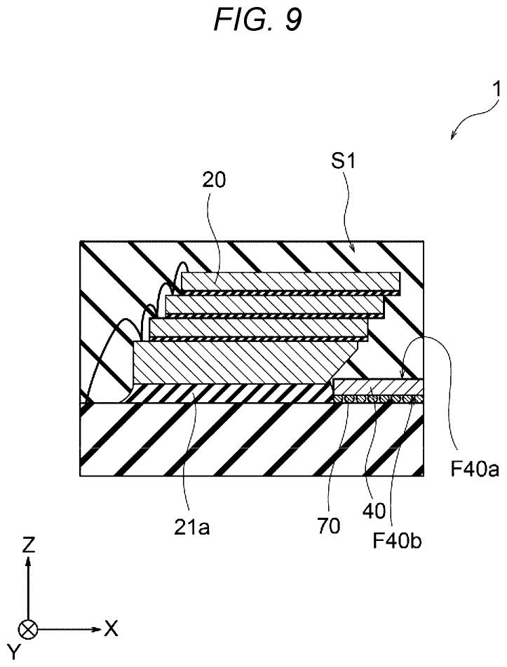

FIG. 9 is a sectional view showing a configuration of the semiconductor device 1 according to a second embodiment. The second embodiment differs from the first embodiment in that the resin layer 80 is not provided. FIG. 9 shows a configuration of a periphery of the stacked body 1.

In the example shown in FIG. 9, the resin layer 80 is not provided when mounting the semiconductor chip 40 on the wiring substrate 10 (see FIG. 4D). In this case, the sealing resin 91 enters a region between the semiconductor chip 40 and the wiring substrate 10 when forming the sealing resin 91 (see FIG. 4G).

An end surface of the resin layer 80 on a side opposite to that of the semiconductor chip 40 has a form that, for example, follows the semiconductor chip 40 and a side surface of the metal material 70.

In the example shown in FIG. 9, the adhesive layer 21a enters a region below the semiconductor chip 40. Meanwhile, the adhesive layer 21a is not provided above the semiconductor chip 40. The adhesive layer 21a may also be above the semiconductor chip 40.

The resin layer 80 need not be provided, as is the case in the second embodiment. Advantages the same as those in the first embodiment can be obtained with the semiconductor device 1 according to the second embodiment.

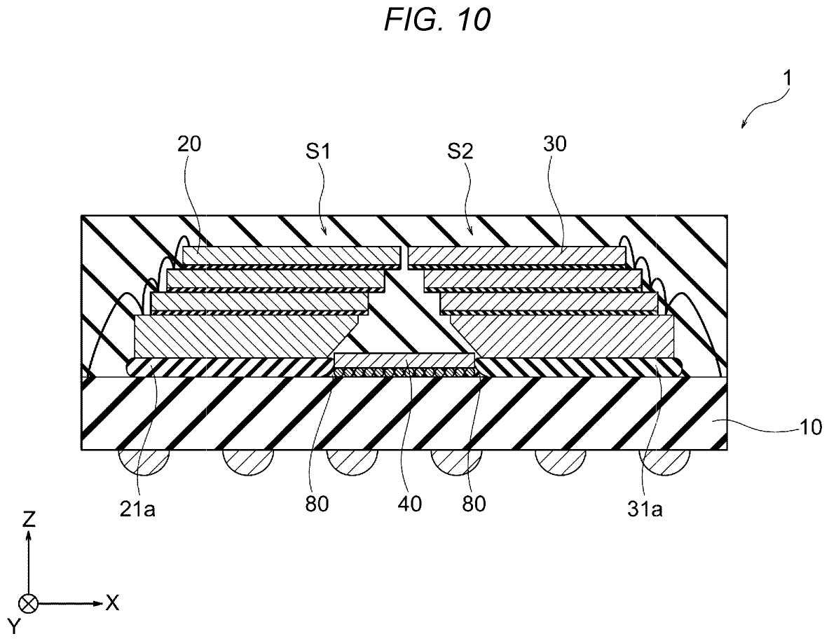

FIG. 10 is a sectional view showing a configuration of the semiconductor device 1 according to a third embodiment. In the third embodiment, configurations of the adhesive layers 21a and 31a differ.

The adhesive layer 21a is a DAF.

A viscosity of a DAF is higher than a viscosity of an NCP. A form of the adhesive layer 21a protruding from the lowermost semiconductor chip 20 is determined in accordance with the viscosity of the adhesive layer 21a. An end surface of the adhesive layer 21a on a side opposite to that of the semiconductor chip 40 has a rounded, protruding form. An end surface of the adhesive layer 21a on the semiconductor chip 40 side has a form that follows an end surface of the resin layer 80 and a side surface of the semiconductor chip 40.

In the example shown in FIG. 10, the adhesive layers 21a and 31a are not provided above the semiconductor chip 40.

The adhesive layer 31a is a DAF.

A form of the adhesive layer 31a is approximately the same as the form of the adhesive layer 21a.

The configurations of the adhesive layers 21a and 31a may be changed, as is the case in the third embodiment. Advantages the same as those in the first embodiment can be obtained with the semiconductor device 1 according to the third embodiment.

Next, a method of manufacturing the semiconductor device 1 of the third embodiment will be described.

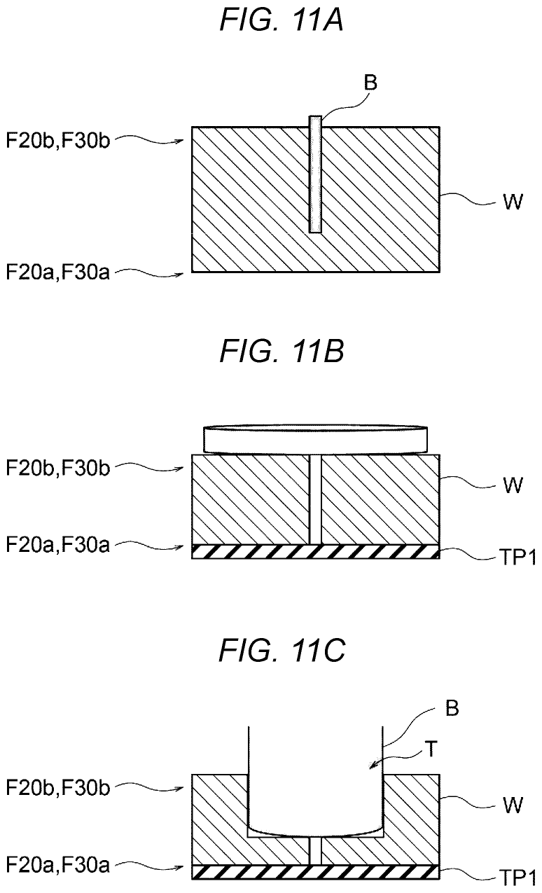

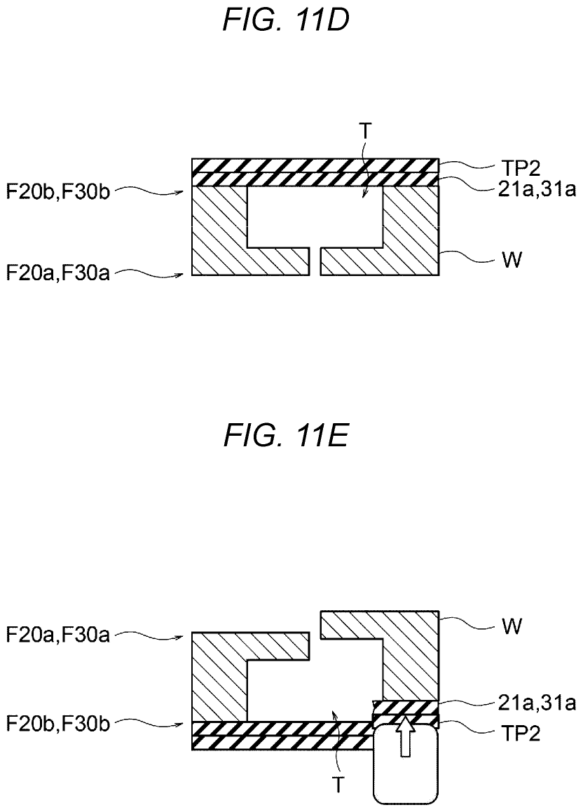

FIGS. 11A to 11E are sectional views showing a method of manufacturing the semiconductor device 1 according to the third embodiment. FIGS. 11A to 11E show processes of the adhesive layers 21a and 31a being formed on the wafer W, on which semiconductor elements of the semiconductor chips 20 and 30 are formed, and singulated. FIGS. 11A to 11E show processes of the adhesive layers 21a and 31a being shredded at a timing at which the semiconductor chips 20 and 30 are picked up.

Firstly, FIGS. 11A to 11E will be described.

Firstly, as shown in FIG. 11A, dicing is carried out using the comparatively thin blade B.

Next, as shown in FIG. 11B, a protective tape TP1 is affixed to the surfaces F20a and F30a, and grinding of the surfaces F20b and F30b is carried out.

Next, as shown in FIG. 11C, dicing is carried out using the comparatively thick blade B. By so doing, the recessed portion T is formed. Dicing may be carried out using the comparatively thin blade B by shifting the dicing position in a horizontal direction in FIG. 11C.

Next, as shown in FIG. 11D, a dicing tape TP2 to which the adhesive layers 21a and 31a are attached is affixed to the surfaces F20b and F30b.

Next, as shown in FIG. 11E, picking up of the singulated semiconductor chips 20 and 30 is carried out. The adhesive layers 21a and 31a are shredded during this picking up. End portions of the shredded adhesive layers 21a and 31a may extend farther than end portions of the surfaces F20b and F30b, as shown in FIG. 11E.

The configurations of the adhesive layers 21a and 31a may be changed, as is the case in the third embodiment. Advantages the same as those in the first embodiment can be obtained with the semiconductor device 1 according to the third embodiment.

### Modification of Third Embodiment

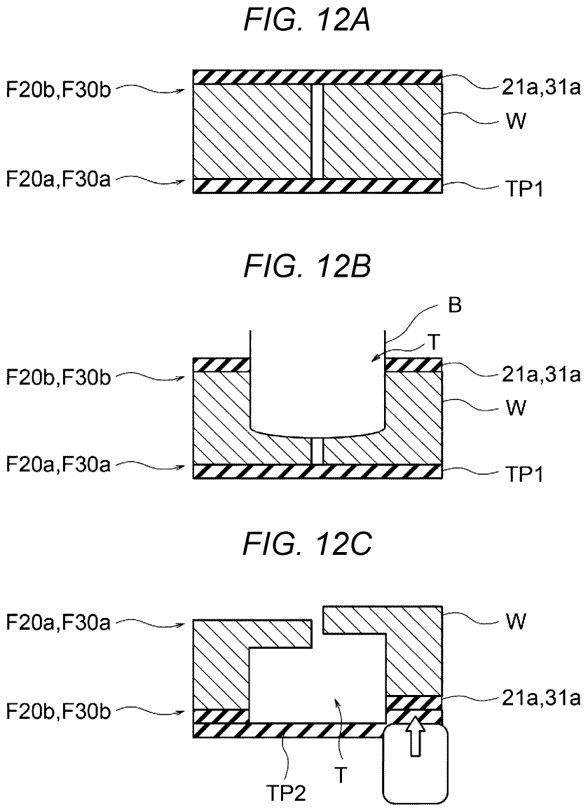

FIGS. 12A to 12C are sectional views showing a method of manufacturing the semiconductor device 1 according to a modification of the third embodiment. In this modification, a method of cutting through the adhesive layers 21a and 31a differs in comparison with that of the third embodiment.

A process shown in FIG. 12A is carried out after processes the same as those in FIGS. 11A and 11B.

After the attachment of the protective tape TP1 and the grinding (see FIG. 11B), the adhesive layers 21a and 31a are affixed to the surfaces F20b and F30b, as shown in FIG. 12A.

Next, as shown in FIG. 12B, dicing is carried out using the comparatively thick blade B. By so doing, the adhesive layers 21a and 31a are cut through, and the recessed portion T is formed. Dicing may be carried out using the comparatively thin blade B by shifting the dicing position in a horizontal direction in FIG. 12B.

Next, as shown in FIG. 12C, the dicing tape TP2 is affixed to the adhesive layers 21a and 31a, and picking up of the singulated semiconductor chips 20 and 30 is carried out. As shown in FIG. 12C, positions of end portions of the adhesive layers 21a and 31a cut through using the blade B are approximately the same as positions of end portions of the surfaces F20b and F30b.

The method of cutting through the adhesive layers 21a and 31a may be changed, as is the case in the modification of the third embodiment. Advantages the same as those in the third embodiment can be obtained with the semiconductor device 1 according to the modification of the third embodiment.

### Fourth Embodiment

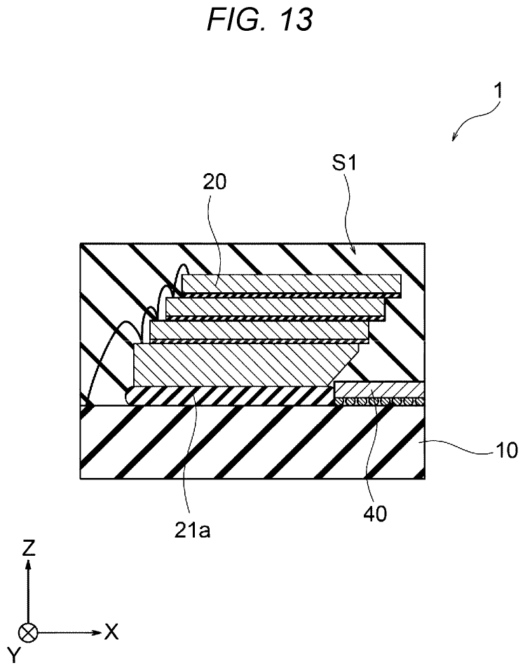

FIG. 13 is a sectional view showing a configuration of the semiconductor device 1 according to a fourth embodiment. The fourth embodiment differs from the third embodiment in that the resin layer 80 is not provided. Consequently, the fourth embodiment is a combination of the second embodiment and the third embodiment. FIG. 13 shows a configuration of a periphery of the stacked body 1.

The resin layer 80 need not be provided, as is the case in the fourth embodiment. Advantages the same as those in the third embodiment can be obtained with the semiconductor device 1 according to the fourth embodiment.

### Fifth Embodiment

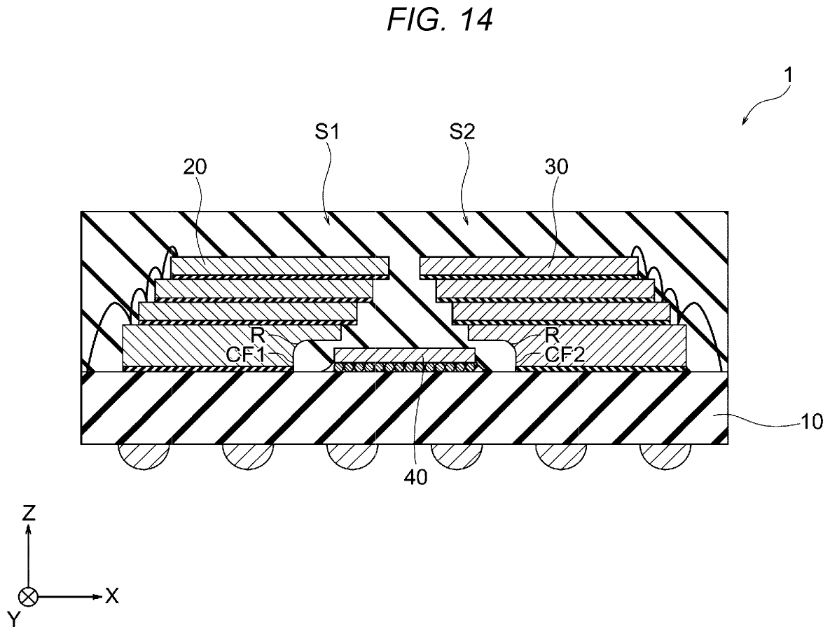

FIG. 14 is a sectional view showing a configuration of the semiconductor device 1 according to a fifth embodiment. In the fifth embodiment, a form of the cutout surfaces CF1 and CF2 differs in comparison with that of the first embodiment.

The cutout surfaces CF1 and CF2 have an L shape. Also, the cutout surfaces CF1 and CF2 have a roundness R in a corner portion of the L shape. Because of this, stress concentration can be restricted. A radius of curvature of the roundness R is determined in accordance with, for example, the comparatively thick blade B shown in FIG. 4C. The radius of curvature of the roundness R may be calculated to be a size that is one-half of a width of the blade B. For example, when the width of the blade B is from 12.5±2.5 μm to 105±5 μm, the radius of curvature of the roundness R is from 5 μm to 55 μm.

The form of the cutout surfaces CF1 and CF2 may be changed, as is the case in the fifth embodiment. Advantages the same as those in the first embodiment can be obtained with the semiconductor device 1 according to the fifth embodiment.

### Sixth Embodiment

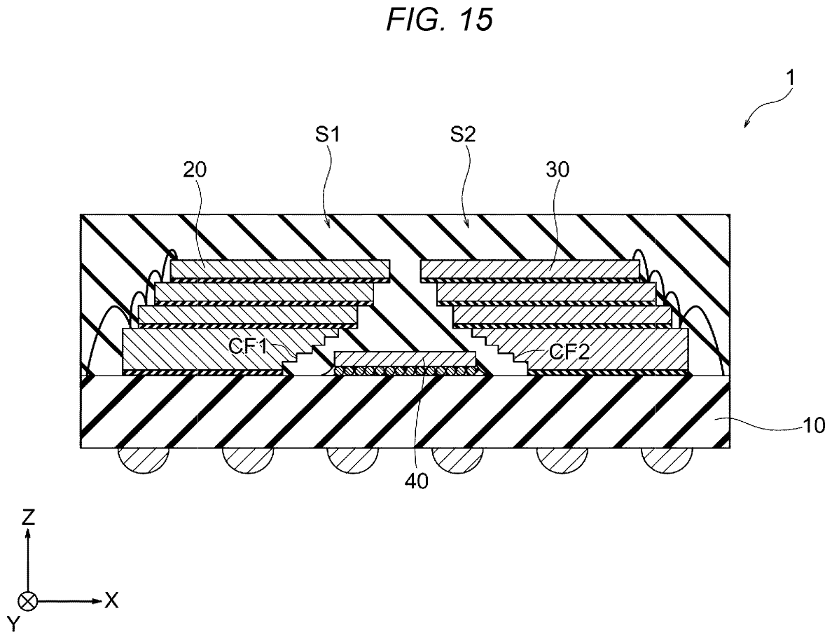

FIG. 15 is a sectional view showing a configuration of the semiconductor device 1 according to a sixth embodiment. In the sixth embodiment, a form of the cutout surfaces CF1 and CF2 differs in comparison with that of the first embodiment.

The cutout surfaces CF1 and CF2 have a stepped shape. The steps of the cutout surfaces CF1 and CF2 have a multiple of step surfaces in order that a corner at which stress is liable to concentrate is unlikely to be formed. Consequently, the cutout surfaces CF1 and CF2 have an inclination. Because of this, stress concentration can be restricted.

The form of the cutout surfaces CF1 and CF2 may be changed, as is the case in the sixth embodiment. Advantages the same as those in the first embodiment can be obtained with the semiconductor device 1 according to the sixth embodiment.

### Seventh Embodiment

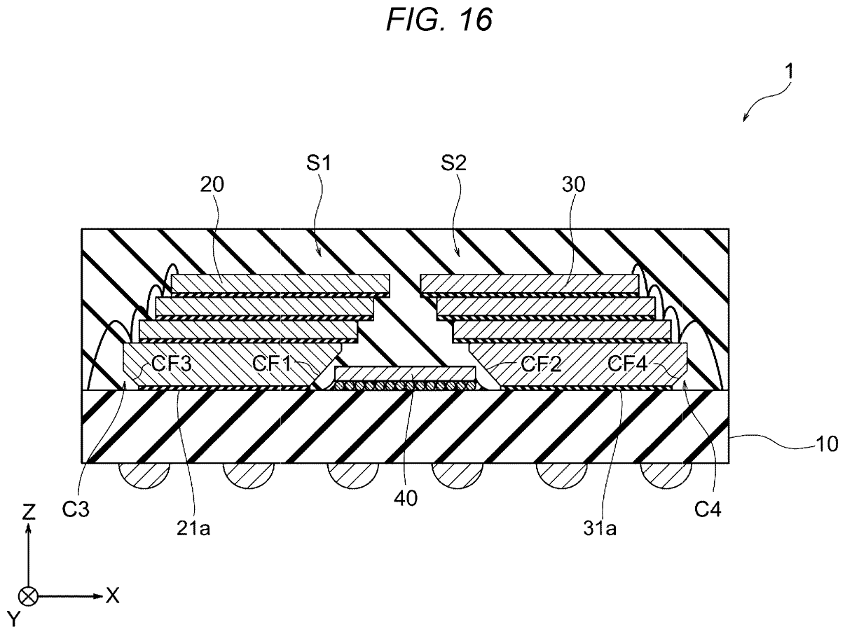

FIG. 16 is a sectional view showing a configuration of the semiconductor device 1 according to a seventh embodiment. In the seventh embodiment, a form of the surfaces F20b and F30b differs in comparison with that of the first embodiment.

An outer edge of the surface F20b on a side opposite to that of the semiconductor chip 40 is farther to an inner side than an outer edge of the surface F20a when seen from the Z direction.

The lowermost semiconductor chip 20 further has a cutout portion C3. The cutout portion C3 is provided in a corner portion in which a side surface between the surface F20b and the surface F20a and the surface F20b intersect. The cutout portion C3 is provided on a side opposite to that of the semiconductor chip 40.

An outer edge of the surface F30b on a side opposite to that of the semiconductor chip 40 is farther to an inner side than an outer edge of the surface F30a when seen from the Z direction.

The lowermost semiconductor chip 30 further has a cutout portion C4. The cutout portion C4 is provided in a corner portion in which a side surface between the surface F30b and the surface F30a and the surface F30b intersect. The cutout portion C4 is provided on a side opposite to that of the semiconductor chip 40.

Owing to the cutout portions C3 and C4 being provided, the adhesive layers 21a and 31a protruding from the lowermost semiconductor chips 20 and 30 collect in the cutout portions C3 and C4. Because of this, a crawling up of the adhesive layers 21a and 31a can be restricted.

The cutout portions C3 and C4, not being limited to the side opposite to that of the semiconductor chip 40, may be provided on either side.

The form of the surfaces F20b and F30b may be changed, as is the case in the seventh embodiment. Advantages the same as those in the first embodiment can be obtained with the semiconductor device 1 according to the seventh embodiment.

### Eighth Embodiment

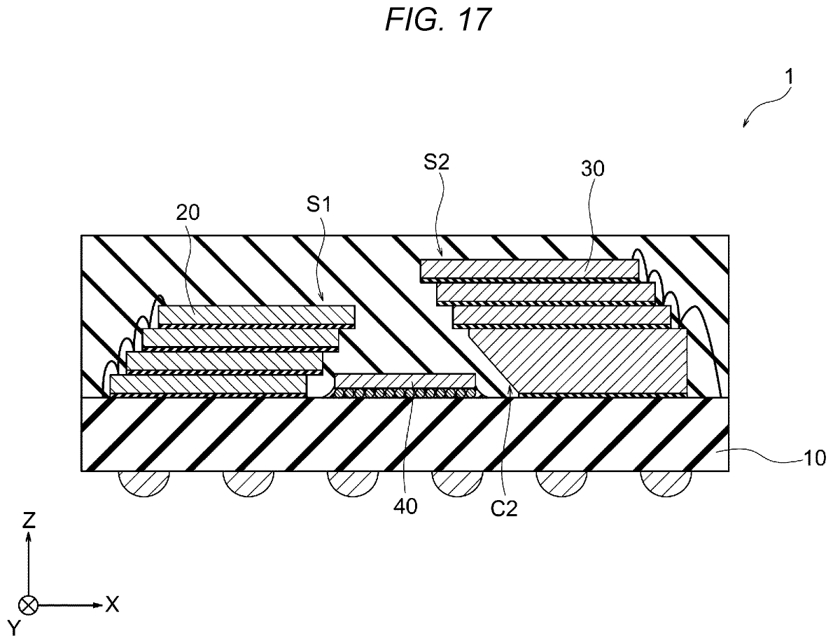

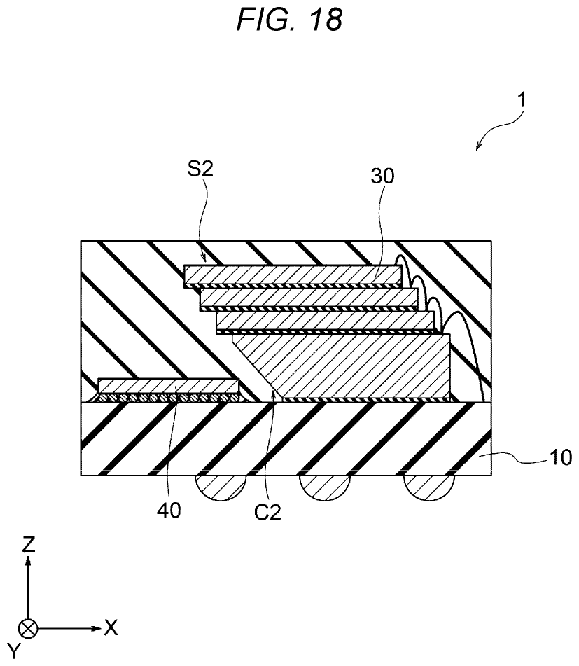

FIG. 17 is a sectional view showing a configuration of the semiconductor device 1 according to an eighth embodiment. The eighth embodiment differs from the first embodiment in that either one of the lowermost semiconductor chips 20 and 30 has the cutout portion C1 or C2.

In the example shown in FIG. 17, a thickness of the lowermost semiconductor chip 20 is approximately the same as a thickness of the semiconductor chips 20 on the second level to the fourth level. Also, the lowermost semiconductor chip 20 may be thicker than the semiconductor chips 20 on the second level to the fourth level. The thicknesses of the semiconductor chip 20 and the semiconductor chip 30 may change variously.

Either one of the lowermost semiconductor chips 20 and 30 may have the cutout portion C1 or C2, as is the case in the eighth embodiment. Advantages the same as those in the first embodiment can be obtained with the semiconductor device 1 according to the eighth embodiment.

### Ninth Embodiment

FIG. 18 is a sectional view showing a configuration of the semiconductor device 1 according to a ninth embodiment. The ninth embodiment differs from the first embodiment in that the stacked body S1 is not provided.

The stacked body S1 may be omitted, as is the case in the ninth embodiment. Advantages the same as those in the first embodiment can be obtained with the semiconductor device 1 according to the ninth embodiment.

### Tenth Embodiment

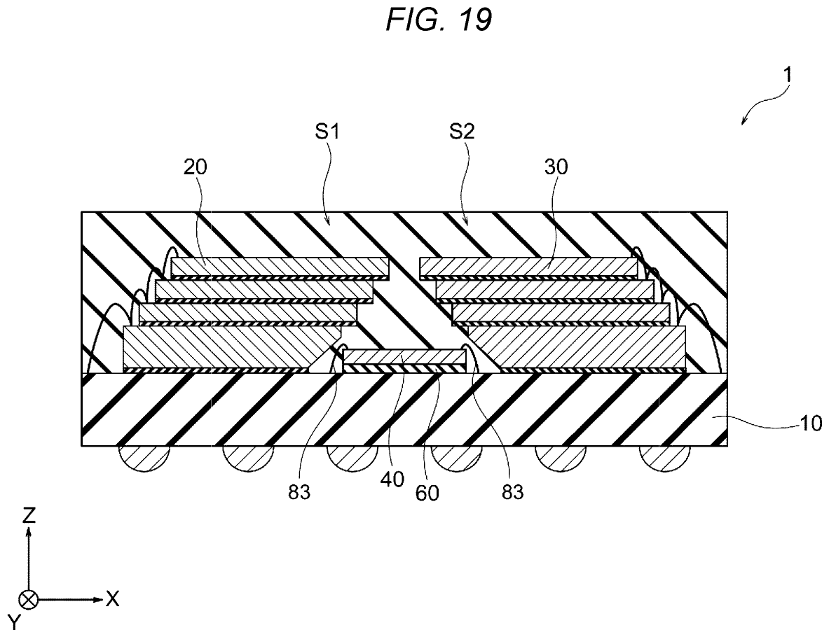

FIG. 19 is a sectional view showing a configuration of the semiconductor device 1 according to a tenth embodiment. The tenth embodiment differs from the first embodiment in that the semiconductor chip 40 is connected using a bonding wire 83.

The semiconductor device 1 further includes an adhesive layer 60 and the bonding wire 83.

The adhesive layer 60 affixes the semiconductor chip 40 to the wiring substrate 10. The adhesive layer 60 is, for example, a DAF.

The bonding wire 83 is connected to any pad of the wiring substrate 10 and the semiconductor chip 40. The bonding wire 83 is, for example, a gold (Au) wire. The semiconductor chip 40 may be connected using the bonding wire 83, as is the case in the tenth embodiment. Advantages the same as those in the first embodiment can be obtained with the semiconductor device 1 according to the tenth embodiment.

### Eleventh Embodiment

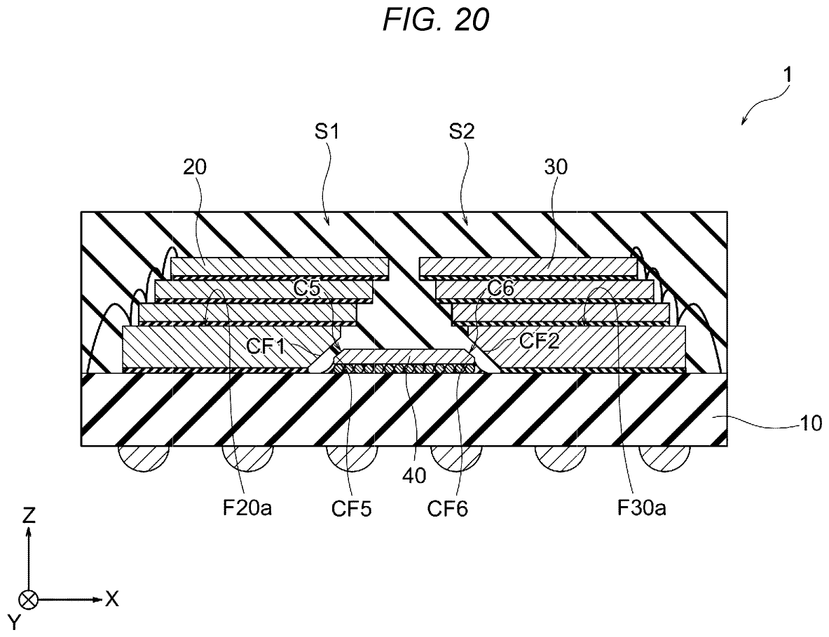

FIG. 20 is a sectional view showing a configuration of the semiconductor device 1 according to an eleventh embodiment. The eleventh embodiment differs from the first embodiment in that the semiconductor chip 40 has cutout portions C5 and C6.

An area of the surface F40a is greater than an area of the surface F40b. Also, an outer edge of the surface F40a on the semiconductor chip 40 side is on an inner side of an outer edge of the surface F40b when seen from the Z direction. An outer edge of the surface F40a on the semiconductor chip 30 side is on an inner side of an outer edge of the surface F40a when seen from the Z direction.

As shown in FIG. 20, the semiconductor chip 40 has the cutout portions C5 and C6. The cutout portions C5 and C6 are provided in a corner portion in which a side surface between the surface F40b and the surface F40a and the surface F40a intersect. The cutout portion C5 is provided on the semiconductor chip 20 side. The cutout portion C6 is provided on the semiconductor chip 30 side.

When seen from the Z direction, at least one portion of a cutout surface CF5 of the cutout portion C5 coincides with the lowermost semiconductor chip 20 (i.e., the surface F20a). In the example shown in FIG. 20, the cutout surface CF5 of the cutout portion C5 is provided inclined with respect to the Z axis and the X axis. That is, the cutout surface CF5 is an inclined surface.

When seen from the Z direction, at least one portion of a cutout surface CF6 of the cutout portion C6 coincides with the lowermost semiconductor chip 30 (i.e., the surface F30a). In the example shown in FIG. 20, the cutout surface CF6 of the cutout portion C6 is provided inclined with respect to the Z axis and the X axis. That is, the cutout surface CF6 is an inclined surface.

Also, the cutout surface CF5 is preferably approximately parallel to the cutout surface CF1. Because of this, the lowermost semiconductor chip 20 and the semiconductor chip 40 can be brought further into proximity.

Also, the cutout surface CF6 is preferably approximately parallel to the cutout surface CF2. Because of this, the lowermost semiconductor chip 30 and the semiconductor chip 40 can be brought further into proximity.

The semiconductor chip 40 may have the cutout portions C5 and C6, as is the case in the eleventh embodiment. Advantages the same as those in the first embodiment can be obtained with the semiconductor device 1 according to the eleventh embodiment.

### Twelfth Embodiment

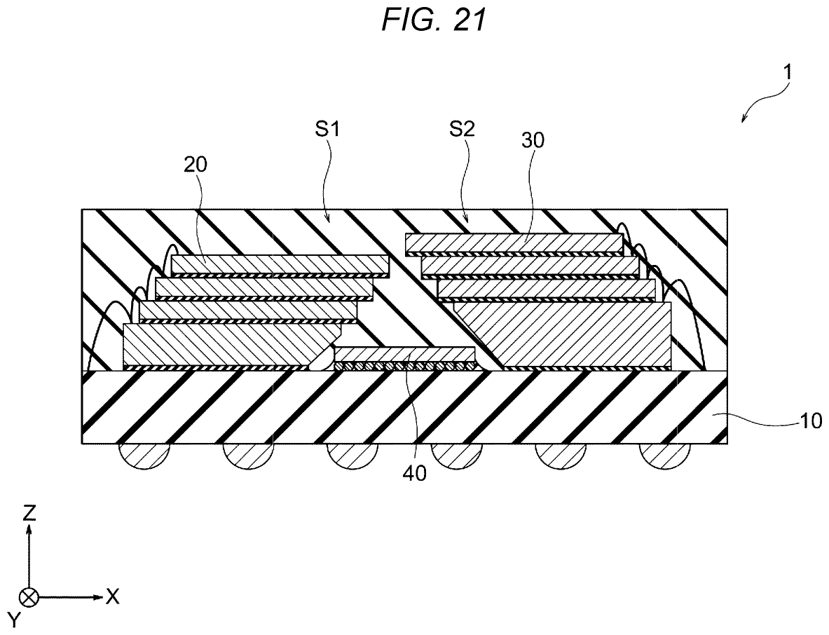

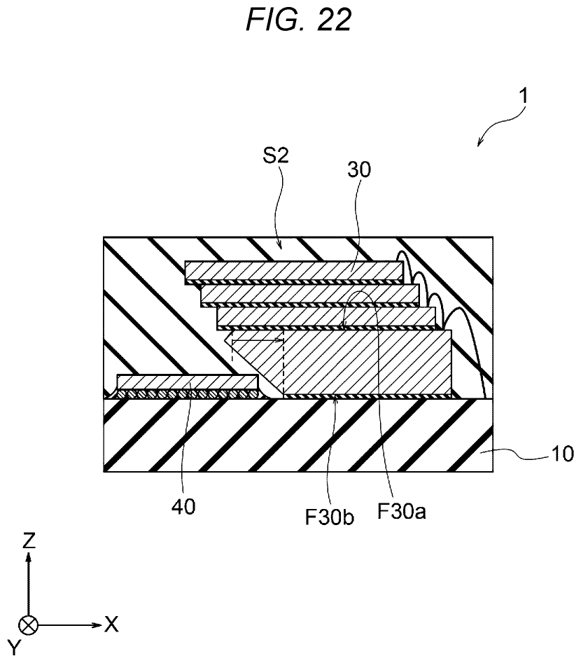

FIG. 21 is a sectional view showing a configuration of the semiconductor

device 1 according to a twelfth embodiment. The twelfth embodiment differs from the first embodiment in that thicknesses differ between the lowermost semiconductor chip 20 and the lowermost semiconductor chip 30.

In the example shown in FIG. 21, the semiconductor chip 30 is thicker than the semiconductor chip 20. Because of this, the stacked body S2 can be brought further into proximity with the stacked body S1. As a result of this, a necessary area of the package can be further reduced.

Thicknesses may differ between the lowermost semiconductor chip 20 and the lowermost semiconductor chip 30, as is the case in the twelfth embodiment. Advantages the same as those in the first embodiment can be obtained with the semiconductor device 1 according to the twelfth embodiment.

### Thirteenth Embodiment

FIG. 22 is a sectional view showing a configuration of the semiconductor device 1 according to a thirteenth embodiment. The thirteenth embodiment differs from the first embodiment in that a side surface of the semiconductor chip 30 has a protruding form. FIG. 22 shows a configuration of a periphery of the stacked body S2.

A side surface between the surface F30a and the surface F30b protrudes toward the semiconductor chip 40 side. When seen from the Z direction, at least one portion of a side surface of the semiconductor chip 40 is farther to the outer side than the surface F30a.

A side surface of the semiconductor chip 30 may have a protruding form, as is the case in the thirteenth embodiment. Advantages the same as those in the first embodiment can be obtained with the semiconductor device 1 according to the thirteenth embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a substrate that includes a first surface;
a first semiconductor chip that includes a second surface facing the first surface of the substrate and a third surface opposite to the second surface, each of the second and third surfaces having a rectangular shape that includes a plurality of sides and has surface areas that are different; and
a second semiconductor chip disposed on the first surface of the substrate on one side of the first semiconductor chip, wherein
when viewed in a first direction substantially perpendicular to the substrate, one of the sides of the third surface that is closest to the second semiconductor chip overlaps an interior portion of the second semiconductor chip.

2. The semiconductor device according to claim 1, wherein the first semiconductor chip includes a first side surface that is on the side of the second semiconductor chip and extends in a second direction parallel to said one of the sides of the third surface and in a third direction that is oblique with respect to both the second and third surfaces.

3. The semiconductor device according to claim 2, further comprising:
a resin layer that covers the first semiconductor chip and contacts the first side surface.

4. The semiconductor device according to claim 2, wherein the first semiconductor chip includes a second side surface that is connected to the first side surface and perpendicular to both the second and third surfaces.

5. The semiconductor device according to claim 1, wherein
the second semiconductor chip includes a fourth surface facing the first surface of the substrate and a fifth surface opposite to the fourth surface, and
when viewed in the first direction, a part of the fourth surface overlaps the first semiconductor chip.

6. The semiconductor device according to claim 5, wherein
the fourth and fifth surfaces of the second semiconductor chip have a rectangular shape including a plurality of sides and surface areas that are different, and
when viewed in the first direction, one of the sides of the fifth surface closest to the first semiconductor chip is farther from a center of the first semiconductor chip than one of the sides of the fourth surface closest to the first semiconductor chip.

7. The semiconductor device according to claim 6, wherein the second semiconductor chip includes a side surface that extends in a second direction parallel to said one of the sides of the fourth surface and said one of the sides of the fifth surface and in a third direction that is oblique with respect to both the fourth and fifth surfaces.

8. The semiconductor device according to claim 1, further comprising:
a third semiconductor chip that includes a sixth surface facing the first surface of the substrate and a seventh surface opposite to the sixth surface, each of the sixth and seventh surfaces having a rectangular shape that includes a plurality of sides and has surface areas that are different, wherein
when viewed in the first direction, one of the sides of the seventh surface that is closest to the second semiconductor chip overlaps an interior portion of the second semiconductor chip.

9. The semiconductor device according to claim 8, wherein
the second semiconductor chip has a rectangular shape including a plurality of sides, and
two of the sides of the semiconductor chip that face each other are parallel to said one of the sides of the second surface, said one of the sides of the third surface, said one of the sides of the sixth surface, and said one of the sides of the seventh surface.

10. The semiconductor device according to claim 1, further comprising:
a fourth semiconductor chip on the third surface of the first semiconductor chip, wherein
a thickness of the first semiconductor chip is greater than a thickness of the fourth semiconductor.

11. The semiconductor device according to claim 10, wherein
the fourth semiconductor chip includes an eighth surface facing the third surface of the first semiconductor chip and a ninth surface opposite to the eighth surface, each of the eighth and ninth surfaces having a rectangular shape that includes a plurality of sides and has substantially the same surface area, and
when viewed in the first direction, each of the sides of the eighth surface approximately coincides with a corresponding one of the sides of the ninth surface.

12. The semiconductor device according to claim 11, wherein when viewed in the first direction, one of the sides of the eighth surface farthest from the second semiconductor chip and one of the sides of the ninth surface corresponding to said one of the sides of the eighth surface overlap an interior portion of the first semiconductor chip.

13. The semiconductor device according to claim 1, further comprising:
an adhesive layer by which the first semiconductor chip adheres to the substrate, wherein
a part of the adhesive layer is between the first and second semiconductor chips, and is closer to the third surface of the first semiconductor chip than the second semiconductor chip in the first direction.

14. The semiconductor device according to claim 1, wherein no spacer is between the substrate and the first semiconductor chip.

15. The semiconductor device according to claim 1, wherein the first semiconductor chip includes a curved side surface that extends parallel to said one of the sides of the third surface and faces the second semiconductor chip.

16. The semiconductor device according to claim 1, wherein the first semiconductor chip includes a side surface having a stepped shape with a plurality of surfaces that extend parallel to said one of the sides of the third surface and face the second semiconductor chip or the first surface of the substrate.

17. The semiconductor device according to claim 1, wherein the first semiconductor chip includes:
a first side surface that is on the side of the second semiconductor chip and extends in a second direction parallel to said one of the sides of the third surface and in a third direction that is oblique with respect to both the second and third surfaces, and
a second side surface that is on the other side of the second semiconductor chip and extends in the second direction and in a fourth direction that is oblique with respect to both the second and third surfaces.

18. A semiconductor device manufacturing method, comprising:
forming a recessed portion in a wafer and singulating the wafer, thereby forming a first semiconductor chip having a first cutout portion corresponding to the recessed portion;
providing the first semiconductor chip on a first surface of a wiring substrate; and
providing a second semiconductor chip on the first surface along a cutout surface of the first cutout portion such that an interior portion of the second semiconductor chip overlaps the cutout surface when viewed in a first direction substantially perpendicular to the first surface.

19. The semiconductor device manufacturing method according to claim 18, further comprising:
before forming the recessed portion, dicing the wafer along a dicing line;
forming an adhesive layer on the wafer in which the recessed portion has been formed along the dicing line; and
picking up the first semiconductor chip in such a way that the adhesive layer is shredded.

20. The semiconductor device manufacturing method according to claim 18, further comprising:
before forming the recessed portion, dicing the wafer along a dicing line, and then forming an adhesive layer on the wafer, wherein
the recessed portion is formed along the dicing line in such a way as to cut through the adhesive layer.
